(19) United States
(12) Patent Application Publication
(10) Pub. No.: US 2018/0175132 A1
(43) Pub. Date: Jun. 21, 2018

(54) ORGANIC LIGHT EMITTING DIODE AND ORGANIC LIGHT EMITTING DISPLAY DEVICE INCLUDING THE SAME

(71) Applicant: Seoul National University R&DB Foundation, Seoul (KR)

(72) Inventors: Chang Hee Lee, Seoul (KR); Yeon Kyung Lee, Seoul (KR)

(73) Assignee: Seoul National University R&DB Foundation, Seoul (KR)

(21) Appl. No.: 15/848,820

(22) Filed: Dec. 20, 2017

(30) Foreign Application Priority Data
Dec. 20, 2016 (KR) 10-2016-0174916

(51) Int. Cl. H01L 27/32; H01L 51/52; H01L 51/50

(52) U.S. Cl. CPC H01L 27/3276; H01L 51/5072; H01L 51/5056; H01L 51/5203

(57) ABSTRACT

Provided herein is an organic light emitting diode including a first electrode, a hole transfer layer disposed on the first electrode, an emission layer disposed on the hole transfer layer and including quantum dots, an electron transfer layer disposed on the emission layer and including a Group III transition metal, and a second electrode disposed on the electron transfer layer.

STATEMENT REGARDING FOREIGN GOVERNMENT SPONSORED RESEARCH OR DEVELOPMENT

This invention was made with the support of Ministry of Science, ICT and Future Planning (MSIP) and National Research Foundation of Korea (NRF) (Research No. 0414-20160040), Ministry of Education (MOE) and NRF (Research No. 5264-20160100), and Ministry of Trade, Industry and Energy (MOTIE) and Korea Evaluation Institute of Industrial Technology (KEIT) (Research No. 0414-20170075).

### CROSS-REFERENCE TO RELATED APPLICATION

This application claims priority from Korean Patent Application No. 10-2016-0174916, filed on Dec. 20, 2016, in the Korean Intellectual Property Office, the disclosure of which is incorporated herein by reference in its entirety.

### BACKGROUND

### 1. Field

The present disclosure relates to an organic light emitting diode and an organic light emitting display device including the same, and more particularly, to an organic light emitting diode including quantum dots, and an organic light emitting display device including the same.

### 2. Description of the Related Art

Monitors, TVs, and the like have recently been required to be lighter and thinner, and thus, to meet such requirement, cathode ray tubes (CRTs) are being replaced by liquid crystal displays (LCDs). However, LDCs, which are non-emissive devices, not only require a separate backlight, but also have limitations in terms of response speed, viewing angle, and the like.

Recently, organic light emitting display devices, which are self-emissive display devices and have a wide viewing angle, high contrast, and rapid response time, have received much attention as a display device capable of overcoming these limitations.

An organic light emitting display device includes an organic light emitting diode to emit light, and such an organic light emitting diode emits light such that electrons injected from one electrode and holes injected from another electrode combine with each other in an emission layer to form excitons, and the excitons emit energy.

Meanwhile, active research and development have recently been carried out on a light emitting diode of an organic light emitting display device in which a wide range of emission wavelengths is controllable through adjustment of the particle size of semiconductor crystals, and the application of quantum dots capable of realizing high color purity and color reproducibility to such a light emitting diode.

### SUMMARY

The present disclosure provides an organic light emitting diode including quantum dots that has high stability and high luminous efficiency due to balanced injection of holes and electrons, and an organic light emitting display device including the same.

According to an embodiment of the present disclosure, an organic light emitting diode includes a first electrode, a hole transfer layer disposed on the first electrode, an emission layer disposed on the hole transfer layer and including quantum dots, an electron transfer layer disposed on the emission layer and including a Group III transition metal, and a second electrode disposed on the electron transfer layer.

The Group III transition metal may include at least one selected from scandium (Sc), yttrium (Y), lanthanum (La), actinium (Ac), ruthenium (Ru), and lawrencium (Lr).

The electron transfer layer may further include at least one selected from a metal oxide, an organic material, and an organic-inorganic composite.

The Group III transition metal may be included in an amount of about 1 wt % to about 10 wt % with respect to a total weight of the electron transfer layer.

The hole transfer layer may include a hole injection layer and a hole transport layer, and the electron transfer layer may include an electron injection layer and an electron transport layer.

The quantum dots may include at least one selected from a Group II-VI compound, a Group III-V compound, a Group IV-VI compound, and a Group IV compound.

According to another embodiment of the present disclosure, an organic light emitting display device includes a substrate, a thin film transistor disposed on the substrate, a first electrode connected to the thin film transistor, a hole transfer layer disposed on the first electrode, an emission layer disposed on the hole transfer layer and including quantum dots, an electron transfer layer disposed on the emission layer and including a Group III transition metal, and a second electrode disposed on the electron transfer layer.

### BRIEF DESCRIPTION OF THE DRAWINGS

The above and other objects, features and advantages of the present disclosure will become more apparent to those of ordinary skill in the art by describing in detail exemplary embodiments thereof with reference to the accompanying drawings, in which:

FIG. 1 is a cross-sectional view of an organic light emitting display device according to an embodiment of the present disclosure;

FIG. 2 is an enlarged partial cross-sectional view of a portion X of an organic light emitting diode of FIG. 1;

FIG. 3 is a graph showing measurement results of electron mobility of each of organic light emitting diode according to Example of the present disclosure and Comparative Example;

FIG. 4 is a graph showing measurement results of current efficiency with respect to luminance of each of the organic light emitting diodes of Example of the present disclosure and Comparative Example; and

FIG. 5 is a graph showing measurement results of lifespan characteristics of the organic light emitting diodes according to Example of the present disclosure and Comparative Example.

### DETAILED DESCRIPTION

Hereinafter, embodiments of the present disclosure will be described in detail with reference to the accompanying drawings in such a way that it may be easily carried out by one of ordinary skill in the art to which the present disclosure pertains. However, the present disclosure may be embodied in many different forms, and is not limited by the embodiments set forth herein.

In the drawings, the thickness of each of a plurality of layers and regions may be exaggerated for clear explanation. Throughout the specification, like reference numerals denote like elements. It will be understood that when an element such as a layer, a film, a region, a plate, or the like is referred to as being “on” another element, it can be directly on the other element or intervening elements may also be present. In contrast, when an element is referred to as being “directly on” another element, there are no intervening elements present.

Hereinafter, an organic light emitting display device according to an embodiment of the present disclosure will be described in detail with reference to the accompanying drawings. In this regard, a structure of the organic light emitting display device includes structures of a driving thin film transistor and an emission layer.

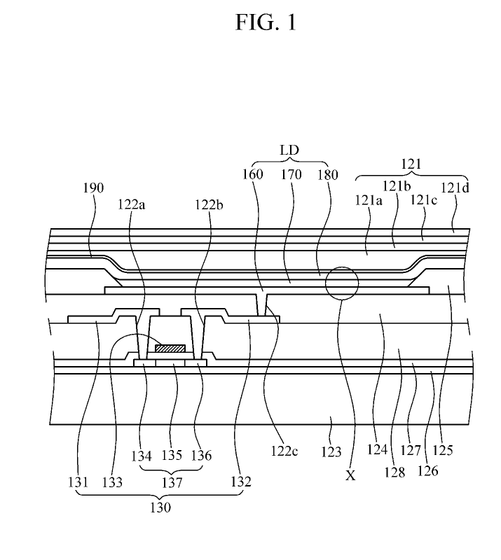

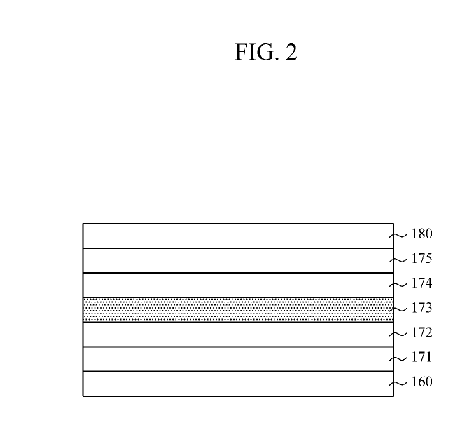

First, an organic light emitting diode according to an embodiment of the present disclosure and an organic light emitting display device including the same will be described in detail with reference to FIGS. 1 and 2.

FIG. 1 is a cross-sectional view of an organic light emitting display device according to an embodiment of the present disclosure. FIG. 2 is an enlarged cross-sectional view of a portion X of an organic light emitting diode of FIG. 1.

Referring to FIGS. 1 and 2, the organic light emitting display device according to an embodiment of the present disclosure includes a substrate 123, a thin film transistor 130, a first electrode 160, a light emitting diode layer 170, and a second electrode 180.

The light emitting diode layer 170 may include hole transfer layers 171 and 172, an emission layer 173, and electron transfer layers 174 and 175. The hole transfer layers 171 and 172 may include a hole injection layer 171 and a hole transport layer 172. The electron transfer layers 174 and 175 may include an electron transport layer 174 and an electron injection layer 175.

The first electrode 160 may be an anode, and the second electrode 180 may be a cathode, or the first electrode 160 may be a cathode, and the second electrode 180 may an anode.

In this case, the substrate 123 may be an insulating substrate made of glass, quartz, ceramic, plastic, or the like. However, an embodiment of the present disclosure is not limited to the above example, and the substrate 123 may be a metallic substrate made of stainless steel, or the like, and may also be made of one organic material selected from polycarbonates, polymethylmethacrylate, polyethylene terephthalate, polyethylene naphthalate, polyamides, polyethersulfone, and polyimides, a combination of these organic materials, a silicon wafer, or the like.

In addition, a substrate buffer layer 126 is positioned on the substrate 123. The substrate buffer layer 126 prevents impurity elements from permeating the substrate 123, and serves to planarize a surface thereof.

In this case, the substrate buffer layer 126 may be formed of one of various materials capable of preventing impurity elements from permeating the substrate 123 and planarizing a surface thereof. For example, as the substrate buffer layer 126, any one of a silicon nitride (SiNx) film, a silicon oxide (SiOᵥ) film, and a silicon oxynitride (SiOₓNᵥ) film may be used. However, the substrate buffer layer 126 is not an essential element, and may be omitted according to the type and manufacturing conditions of the substrate 123.

A driving semiconductor layer 137 is formed on the substrate buffer layer 126. The driving semiconductor layer 137 is formed as a polycrystalline silicon film. In addition, the driving semiconductor layer 137 includes an impurity-undoped channel region 135, and doped source and drain regions 134 and 136 formed on opposite sides of the channel region 135. In this case, a doped ionic material is a P-type impurity such as boron (B), mainly B2H6. In this regard, these impurities may vary according to the type of thin film transistor.

A gate insulating layer 127 formed of silicon nitride (SiNₓ) or silicon oxide (SiOᵥ) is formed on the driving semiconductor layer 137. A gate wiring including a driving gate electrode 133 is formed on the gate insulating layer 127. In addition, the driving gate electrode 133 is configured to overlap at least a portion, in particular, the channel region 135, of the driving semiconductor layer 137.

Meanwhile, an interlayer insulating layer 128 is formed on the gate insulating layer 127 to cover the driving gate electrode 133. A first contact hole 122a and a second contact hole 122b are formed in the gate insulating layer 127 and the interlayer insulating layer 128 to respectively expose the source region 134 and the drain region 136 of the driving semiconductor layer 137. Similar to the gate insulating layer 127, the interlayer insulating layer 128 may be formed of a ceramic-based material such as silicon nitride (SiNₓ), silicon oxide (SiO_{y}), or the like.

In addition, a data wiring including a driving source electrode 131 and a driving drain electrode 132 is formed on the interlayer insulating layer 128. In addition, the driving source electrode 131 and the driving drain electrode 132 are respectively connected to the source region 134 and the drain region 136 of the driving semiconductor layer 137 via the first contact hole 122a and the second contact hole 122b, respectively, formed in the interlayer insulating layer 128 and the gate insulating layer 127.

As such, the driving thin film transistor 130 is configured to include the driving semiconductor layer 137, the driving gate electrode 133, the driving source electrode 131, and the driving drain electrode 132. The configuration of the driving thin film transistor 130 is not limited to the above example, and this is a known configuration that may be easily realized by one of ordinary skill in the art and may be variously modified.

In addition, a planarizing layer 124 is formed on the interlayer insulating layer 128 to cover the data wiring. The planarizing layer 124 removes a step and performs a planarizing function to increase luminous efficiency of an organic light emitting diode to be formed thereon. In addition, the planarizing layer 124 has a third contact hole 122c to partially expose the drain electrode 132.

The planarizing layer 124 may be formed of at least one selected from an acrylate-based resin, an epoxy resin, a phenolic resin, a polyamide-based resin, a polyimide-based resin, an unsaturated polyester-based resin, a polyphenylene-based resin, a polyphenylenesulfide-based resin, and benzocyclobutene (BCB), or the like.

In this regard, embodiments of the present disclosure are not limited to the above-described structure. In some embodiments, any one of the planarizing layer 124 and the interlayer insulating layer 128 may be omitted.

In addition, the first electrode 160, i.e., a pixel electrode, of an organic light emitting diode (LD) is formed on the planarizing layer 124. That is, the organic light emitting display device includes a plurality of first electrodes 160 respectively arranged for a plurality of pixels. In this case, the first electrodes 160 are spaced apart from each other. The first electrode 160 is connected to the drain electrode 132 via the third contact hole 122c of the planarizing layer 124.

In addition, a pixel defining layer 125 having an opening through which the first electrode 160 is exposed is formed on the planarizing layer 124. That is, the pixel defining layer 125 has a plurality of openings, each being formed for each pixel. In this case, the light emitting diode layer 170 may be formed in each opening formed by the pixel defining layer 125. Accordingly, a pixel region in which each organic emission layer is formed may be defined by the pixel defining layer 125.

In this case, the first electrode 160 is positioned to correspond to the opening of the pixel defining layer 125. However, the first electrode 160 is not positioned only in the opening of the pixel defining layer 125, and the first electrode 160 may be positioned below the pixel defining layer 125 such that the first electrode 160 partially overlaps the pixel defining layer 125.

The pixel defining layer 125 may be formed of a resin selected from a polyacrylate-based resin and a polyimide-based resin, a silica-based inorganic material, or the like.

Meanwhile, the light emitting diode layer 170 is formed on the first electrode 160. A structure of the light emitting diode layer 170 will be described below in detail.

In addition, the second electrode 180, i.e., a common electrode, may be formed on the light emitting diode layer 170. As such, an organic light emitting diode LD including the first electrode 160, the light emitting diode layer 170, and the second electrode 180 is formed.

In this case, the first electrode 160 and the second electrode 180 each independently may be formed of a transparent conductive material or a semi-transmissive or reflective conductive material. Non-limiting examples of these materials include indium tin oxide (ITO), silver (Ag) nanowires, aluminum (Al), Ag, and gold (Au).

The organic light emitting display device may be a top emission type, bottom emission type or dual emission type organic light emitting display device according to types of materials for forming the first electrode 160 and the second electrode 180.

Meanwhile, a cover layer 190 may be formed as an organic film on the second electrode 180 to cover and protect the second electrode 180. In addition, a thin film encapsulation layer 121 is formed on the cover layer 190. The thin film encapsulation layer 121 encapsulates the organic light emitting diode LD and a driving circuit unit, formed on the substrate 123, and thus protects them from the outside.

The thin film encapsulation layer 121 includes encapsulation organic films 121a and 121c and encapsulation inorganic films 121b and 121d that are alternately stacked one by one. For example, FIG. 1 illustrates a case in which two encapsulation organic films 121a and 121c and two encapsulation inorganic films 121b and 121d are alternately stacked one by one to form the thin film encapsulation layer 121, but the present disclosure is not limited to the above example. That is, the structure of the thin film encapsulation layer 121 may be variously modified.

According to need, a color filter (not shown) may also be formed on the thin film encapsulation layer 121 to correspond to each pixel region.

Hereinafter, the organic light emitting diode LD according to an embodiment of the present disclosure will be described in detail with reference to FIG. 2.

The organic light emitting diode LD (see portion X of FIG. 1) according to an embodiment of the present disclosure has a structure in which the first electrode 160, the hole injection layer 171, the hole transport layer 172, the emission layer 173, the electron transport layer 174, the electron injection layer 175, and the second electrode 180 are sequentially stacked.

When the first electrode 160 is formed as an anode, the first electrode 160 may include one selected from materials having a high work function to facilitate hole injection.

According to one embodiment, the first electrode 160 may be formed as a transparent electrode having a small thickness using a conductive oxide such as ITO, indium zinc oxide (IZO), tin oxide (SnO₂), zinc oxide (ZnO), or a combination thereof, or a metal such as Al, Ag, or magnesium (Mg). In addition, the first electrode 160 is not limited to the above example, and may have a stacked structure of two or more layers of a conductive oxide and a metal material.

The hole injection layer 171 may be disposed on the first electrode 160. In this case, the hole injection layer 171 may serve to facilitate injection of holes from the first electrode 160 into the hole transport layer 172.

The hole injection layer 171 may be formed of a material such as 4,4′-bis(N-carbazolyl)-1,1′-biphenyl (CBP), tris(4-carbazoyl-9-ylphenyl)amine (TCTA), poly(9-vinylcarbazole) (PVK), poly(9,9-dioctylfluorene-co-N-(4-butylphenyl)diphenylamine) (TFB), copper phthalocyanine (CuPc), poly(3,4)-ethylenedioxythiophene (PEDOT), polyaniline (PANI), or N,N-dinaphthyl-N,N′-diphenyl benzidine (NPD), but the present disclosure is not limited to the above examples.

The hole injection layer 171 may have a thickness of about 10 nm to about 30 nm.

The hole transport layer 172 may be disposed on the hole injection layer 171. The hole transport layer 172 may serve to smoothly transport holes transferred from the hole injection layer 171.

The hole transport layer 172 may include hexaazatriphenylene-hexacarbonitrile (HAT-CN), molybdenum oxide (MoO₃), tungsten oxide (WO₃), vanadium pentoxide (V₂O₅), N,N-dinaphthyl-N,N′-diphenyl benzidine (NPD), (N,N′-bis-(3-methylphenyl)-N,N′-bis-(phenyl)-benzidine (TPD), s-TAD, 4,4′,4″-tris(N-3-methylphenyl-N-phenyl-amino)-triphenylamine (MTDATA), 4-(9H-carbazol-9-yl)-N,N-bis[4-(9H-carbazol-9-yl)phenyl]-benzenamine (TCTA), 4,4′-N,N′-dicarbazole-biphenyl (CBP), or the like, but the present disclosure is not limited to the above examples.

The hole transport layer 172 may have a thickness of about 20 nm to about 60 nm.

In the present embodiment, the hole injection layer 171 and the hole transport layer 172 form a stacked structure, but the present disclosure is not limited to the above example. That is, the hole injection layer 171 and the hole transport layer 172 may also be formed as a single layer.

The emission layer 173 is formed on the hole transport layer 172. The emission layer 173 includes a light emitting material expressing a particular color. For example, the emission layer 173 may express a basic color such as blue, green, or red, or a combination of these colors.

The light emitting material included in the emission layer 173 of the organic light emitting diode LD according to an embodiment of the present disclosure may include quantum dots.

According to one embodiment, the quantum dots included in the emission layer 173 may include a Group II-VI compound, a Group III-V compound, a Group IV-VI compound, a Group IV compound, or a combination of these compounds.

The Group II-VI compound may be selected from the group consisting of: a binary compound selected from the group consisting of CdSe, CdTe, ZnS, ZnSe, ZnTe, ZnO, HgS, HgSe, HgTe, MgSe, MgS, and mixtures thereof; a ternary compound selected from the group consisting of CdSeS, CdSeTe, CdSTe, ZnSeS,

ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and mixtures thereof; and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and mixtures thereof.

The Group III-V compound may be selected from the group consisting of: a binary compound selected from the group consisting of GaN, GaP, GaAs, GaSb, AlN, AlP, AlAs, AlSb, InN, InP, InAs, InSb, and mixtures thereof; a ternary compound selected from the group consisting of GaNP, GaNAs, GaNSb, GaPAs, GaPSb, AlNP, AlNAs, AlNSb, AlPAs, AlPSb, InNP, InNAs, InNSb, InPAs, InPSb, GaAlNP, and mixtures thereof; and a quaternary compound selected from the group consisting of GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and mixtures thereof.

The Group IV-VI compound may be selected from the group consisting of: a binary compound selected from the group consisting of SnS, SnSe, SnTe, PbS, PbSe, PbTe, and mixtures thereof; a ternary compound selected from the group consisting of SnSeS, SnSeTe, SnSTe, PbSeS, PbSeTe, PbSTe, SnPbS, SnPbSe, SnPbTe, and mixtures thereof; and a quaternary compound selected from the group consisting of SnPbSSe, SnPbSeTe, SnPbSTe, and mixtures thereof.

An element of the Group IV compound may be selected from the group consisting of silicon (Si), germanium (Ge), and mixtures thereof, and the Group IV compound may be a binary compound selected from the group consisting of SiC, SiGe, and mixtures thereof.

In quantum dots including cores and shells, the cores may have an average particle diameter of about 2 nm to about 5 nm. Meanwhile, the shells may have an average thickness of about 3 nm to about 5 nm. In addition, the quantum dots may have an average particle diameter of about 5 nm to about 10 nm. When the cores, the shells, and the quantum dots satisfy the above-described average particle diameter and average thickness ranges, the quantum dots may show the characteristic behavior of quantum dots and may also have excellent dispersibility. By variously selecting the average particle diameter of the cores, the average thickness of the shells, and the average particle diameter of the quantum dots from the above-described ranges, light emitting colors and/or semiconductor characteristics of the quantum dots may be variously modified.

The type of the quantum dots is not particularly limited as long as the quantum dots are of a generally used type, and the quantum dots may be, for example, in the form of nanoparticles, nanotubes, nanowires, nanofibers, nanoplatelet particles, or the like which have a spherical shape, a pyramidal shape, a multi-arm shape, or a cubic shape.

In addition, the quantum dot may further include a ligand formed at a surface of the shell via chemical bonding therebetween. The ligand may include an organic functional group, and the organic functional group may include, for example, an oleate, trioctylphosphine, and the like.

In this case, the emission layer 173 may have a thickness of about 15 nm to about 35 nm.

In addition, the electron transport layer 174 and the electron injection layer 175 may be disposed on the emission layer 173.

In this case, the electron transport layer 174 may transfer electrons from the second electrode 180 to the emission layer 173. In addition, the electron transport layer 174 may prevent holes injected from the first electrode 160 from moving to the second electrode 180 after passing through the emission layer 173. That is, the electron transport layer 174 acts as a hole blocking layer, and thus helps the combining of holes and electrons in the emission layer 173.

In addition, the electron injection layer 175 may serve to facilitate injection of electrons from the second electrode 180 into the electron transport layer 174.

According to the present embodiment, the electron transport layer 174 and the electron injection layer 175 form a stacked structure, but may also be formed as a single layer.

The electron transport layer 174 and the electron injection layer 175 may include a metal oxide, an organic material, or an organic-inorganic composite, for example, any one or more selected from In₂S₃, Cu₂S, Ag₂S, ZnSe, ZnS, ZnO, ZnTe, ZnSe, TiO₂, SnO₂, and ZnS, but the present disclosure is not limited to the above examples.

In addition, at least one of the electron transport layer 174 and the electron injection layer 175 of the organic light emitting diode LD according to an embodiment of the present disclosure may further include a Group III transition metal.

That is, at least one of the electron transport layer 174 and the electron injection layer 175 of the organic light emitting diode LD according to an embodiment of the present disclosure includes at least one of scandium (Sc), yttrium (Y), lanthanum (La), actinium (Ac), ruthenium (Ru), and lawrencium (Lr).

In this regard, the Group III transition metal may be included in an amount of about 1 wt % to about 10 wt % with respect to a total weight of the electron transport layer 174 and/or the electron injection layer 175.

A total thickness of the electron transport layer 174 and the electron injection layer 175 may range from about 30 nm to about 60 nm.

The second electrode 180 is formed on the electron injection layer 175. In the organic light emitting display device according to an embodiment of the present disclosure, the first electrode 160 is an anode, and the second electrode 180 may be a cathode. Similarly, the second electrode 180 may be formed as a transparent electrode having a small thickness using a conductive oxide such as ITO, IZO, SnO₂, ZnO, or a combination thereof, or a metal such as Al, Ag, or Mg. In addition, the second electrode 180 is not limited to the above example, and may have a stacked structure of two or more layers of a conductive oxide and a metal material.

Hereinafter, configurations of the present disclosure and effects according thereto will be described in further detail with reference to the following example and comparative example. However, the example is provided for illustrative purposes only and is not intended to limit the scope of the present disclosure.

### EXAMPLE

ITO having a resistance of 10 to 15 Ω/□ and a thickness of 150 nm was formed as a first electrode on a 0.7 mm glass substrate.

Zinc acetate and yttrium nitrate hexahydrate were added to ethanol to prepare a homogeneously mixed solution, and the solution was spin-coated on the first electrode at 3,500 rpm for 40 seconds and heat-treated in air at 450° C. for 2 hours to form an electron transport layer and an electron injection layer, formed as a yttrium-doped zinc oxide thin film having a thickness of 45 nm.

Quantum dots each including a core formed of CdSe and a shell formed of a mixture of CdS and ZnS were spin-coated on the electron transport layer and the electron injection layer at 4,000 rpm for 30 seconds, and then dried at 100° C. for 10 minutes to form an emission layer having a thickness of 25 nm.

Subsequently, CBP was deposited on the emission layer by vacuum deposition to form a hole transport layer having a thickness of 60 nm, and molybdenum oxide (MoO₃) was deposited on the hole transport layer by vacuum deposition to form a hole injection layer having a thickness of 10 nm.

Next, aluminum was vacuum-deposited on the hole injection layer to form a second electrode having a thickness of 120 nm, thereby completing the manufacture of an organic light emitting diode.

### Comparative Example

An organic light emitting diode was manufactured in the same manner as in Example, except that the zinc oxide thin film formed as an electron transport layer and an electron injection layer was undoped with yttrium.

### Experimental Example 1

### Measurement of Electron Mobility

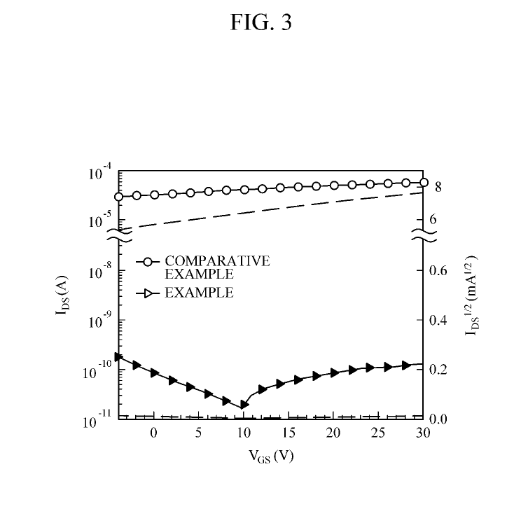

To measure electron mobility of each of the organic light emitting diodes manufactured according to Example and Comparative Example, electrical characteristics of each organic light emitting diode were measured by applying power thereto using a Keithley 237 source meter, and the results thereof are shown in FIG. 3.

FIG. 3 is a graph showing measurement results of electron mobility of each of the organic light emitting diode according to Example of the present disclosure and Comparative Example.

As illustrated in FIG. 3, it was confirmed that the organic light emitting diodes according to Example had an electron mobility of 2.76×10⁻⁷ cm²/V.s, which is lower than the electron mobility, i.e., 0.0185 cm²/V.s, of the organic light emitting diode according to Comparative Example.

### Experimental Example 2

### Measurement of Current Efficiency with Respect to Luminance

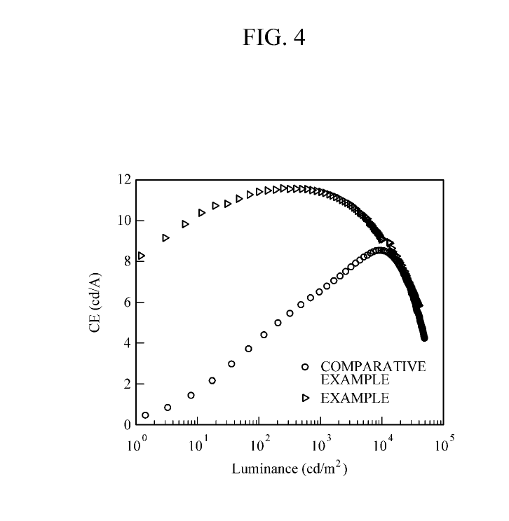

To measure current efficiency with respect to luminance of the organic light emitting diodes according to Example and Comparative Example, the amount of light was measured using a Keithley 2000 multimeter, a silicon photodiode, and a photomultiplier tube while applying power using a Keithley 237 source meter (manufactured by Keithley), electroluminescence spectra were measured using a Minolta CS-2000A spectrometer, and the results thereof are shown in FIG. 4.

FIG. 4 is a graph showing measurement results of current efficiency with respect to luminance of each of the organic light emitting diodes of Example of the present disclosure and Comparative Example.

As illustrated in FIG. 4, it was confirmed that the organic light emitting diode according to Example exhibited at least a 30% increase in current density, compared to the organic light emitting diode according to Comparative Example.

### Experimental Example 3

### Measurement of Lifespan Characteristics

To measure lifespan characteristics of the organic light emitting diodes according to Example and Comparative Example, the time taken until luminance was reduced to 40% of initial luminance was measured using McScience MC620S.

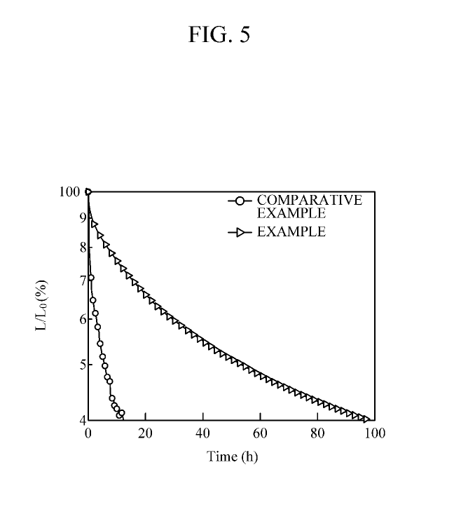

In this case, measurement was carried out by applying current to each of the organic light emitting diodes of Example and Comparative Example such that initial luminance thereof reached 1000 cd/m², and the results thereof are shown in FIG. 5.

FIG. 5 is a graph showing measurement results of lifespan characteristics of the organic light emitting diodes according to Example of the present disclosure and Comparative Example.

As shown in FIG. 5, it was confirmed that the lifespan of the organic light emitting diode according to Example increased by 8 times or more, compared to the organic light emitting diode according to Comparative Example.

As such, it may be confirmed that, in the case of organic light emitting diodes according to embodiments of the present disclosure, an electron transport layer and an electron injection layer have reduced electron mobility, and thus excessive electron injection is prevented, and, accordingly, the balance between electrons and holes in the organic light emitting diodes is adjusted, and the organic light emitting diodes exhibit enhanced efficiency and an enhanced lifespan.

As is apparent from the foregoing description, according to one or more embodiments of the present disclosure, injection of holes and electrons of an organic light emitting diode including quantum dots may be balanced, and thus the organic light emitting diode exhibits high stability and high luminous efficiency.

While exemplary embodiments of the present disclosure have been described in detail, the scope of the present disclosure is not limited by the embodiments, and various changes and modifications made by one of ordinary skill in the art using basic concepts of the present disclosure as defined by the following claims are also within the scope of the present disclosure.

What is claimed is:

1. An organic light emitting diode comprising:
a first electrode;
a hole transfer layer disposed on the first electrode;
an emission layer disposed on the hole transfer layer and comprising quantum dots;
an electron transfer layer disposed on the emission layer and comprising a Group III transition metal; and
a second electrode disposed on the electron transfer layer.

2. The organic light emitting diode of claim 1, wherein the Group III transition metal comprises at least one selected from scandium (Sc), yttrium (Y), lanthanum (La), actinium (Ac), ruthenium (Ru), and lawrencium (Lr).

3. The organic light emitting diode of claim 2, wherein the electron transfer layer further comprises at least one selected from a metal oxide, an organic material, and an organic-inorganic composite.

4. The organic light emitting diode of claim 3, wherein the Group III transition metal is included in an amount of about 1 wt % to about 10 wt % with respect to a total weight of the electron transfer layer.

5. The organic light emitting diode of claim 2, wherein the hole transfer layer comprises a hole injection layer and a hole transport layer, and the electron transfer layer comprises an electron injection layer and an electron transport layer.

6. The organic light emitting diode of claim 2, wherein the quantum dots comprise at least one selected from a Group II-VI compound, a Group III-V compound, a Group IV-VI compound, and a Group IV compound.

7. An organic light emitting display device comprising:
a substrate;
a thin film transistor disposed on the substrate;
a first electrode connected to the thin film transistor;
a hole transfer layer disposed on the first electrode;
an emission layer disposed on the hole transfer layer and comprising quantum dots;
an electron transfer layer disposed on the emission layer and comprising a Group III transition metal; and
a second electrode disposed on the electron transfer layer.

8. The organic light emitting display device of claim 7, wherein the Group III transition metal comprises at least one selected from scandium (Sc), yttrium (Y), lanthanum (La), actinium (Ac), ruthenium (Ru), and lawrencium (Lr).

9. The organic light emitting display device of claim 8, wherein the electron transfer layer further comprises at least one selected from a metal oxide, an organic material, and an organic-inorganic composite, and
the Group III transition metal is included in an amount of about 1 wt % to about 10 wt % with respect to a total weight of the electron transfer layer.

10. The organic light emitting display device of claim 8, wherein the hole transfer layer comprises a hole injection layer and a hole transport layer, and the electron transfer layer comprises an electron injection layer and an electron transport layer.
